(19) United States
(12) Patent Application Publication
(10) Pub. No.: US 2025/0081817 A1
(43) Pub. Date: Mar. 6, 2025

(54) DISPLAY DEVICE

(71) Applicant: Japan Display Inc., Tokyo (JP)

(72) Inventors: Hideyuki TAKAHASHI, Tokyo (JP); Kazuyuki HARADA, Tokyo (JP); Yasuhito ARUGA, Tokyo (JP)

(73) Assignee: Japan Display Inc., Tokyo (JP)

(21) Appl. No.: 18/817,363

(22) Filed: Aug. 28, 2024

(30) Foreign Application Priority Data
Sep. 1, 2023 (JP) 2023-142336

(51) Int. Cl. H10K 59/80; H10K 59/131

(52) U.S. Cl. CPC H10K 59/873; H10K 59/131

(57) ABSTRACT

According to one embodiment, a display device includes a substrate, a display area displaying an image, a surrounding area surrounding the display area, a display element arranged above the substrate, a first sealing layer formed of an inorganic material and covering the display element, a resin layer arranged on the first sealing layer, a second sealing layer formed of an inorganic material and covering the resin layer, a conductive pad arranged in the surrounding area, and a polarizer arranged above the second sealing layer. At least one of an end portion of the first sealing layer and an end portion of the second sealing layer is located closer to the pad than an end portion of the polarizer is.

### CROSS-REFERENCE TO RELATED APPLICATIONS

This application is based upon and claims the benefit of priority from Japanese Patent Application No. 2023-142336, filed Sep. 1, 2023, the entire contents of which are incorporated herein by reference.

### FIELD

Embodiments described herein relate generally to a display device.

### BACKGROUND

Recently, various types of display devices have been proposed. As an example, a display device comprises a polarizer covering a display area and a moisture-proof member in contact with an end portion of the polarizer. The moisture-proof member has a function of preventing moisture from infiltrating a mount area on which a flexible substrate and the like are mounted.

However, contraction of a polarizer due to a

temperature change may form gaps between the polarizer and a moisture-proof member. Moisture may infiltrate mounting area through these gaps.

### BRIEF DESCRIPTION OF THE DRAWINGS

FIG. 1 is a plan view showing a schematic configuration example of a display device.

FIG. 2 is a schematic cross-sectional view of the display device in a display area.

FIG. 3 is a schematic cross-sectional view of the display device along line A-A in FIG. 1.

FIG. 4 is a schematic plan view showing a terminal in enlarged manner.

FIG. 5 is a cross-sectional view showing another configuration example of the display device.

FIG. 6 is a cross-sectional view showing yet another configuration example of the display device.

### DETAILED DESCRIPTION

In general, according to one embodiment, a display device comprises a substrate, a display area displaying an image, a surrounding area surrounding the display area, a display element located above the substrate, a first sealing layer formed of an inorganic material and covering the display element, a resin layer arranged on the first sealing layer, a second sealing layer formed of an inorganic material and covering the resin layer, a conductive pad arranged in the surrounding area, and a polarizer arranged above the second sealing layer. At least one of an end portion of the first sealing layer and an end portion of the second sealing layer is located closer to the pad than an end portion of the polarizer is.

The embodiment can provide a display device capable of preventing moisture from infiltrating the mounting area.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view.

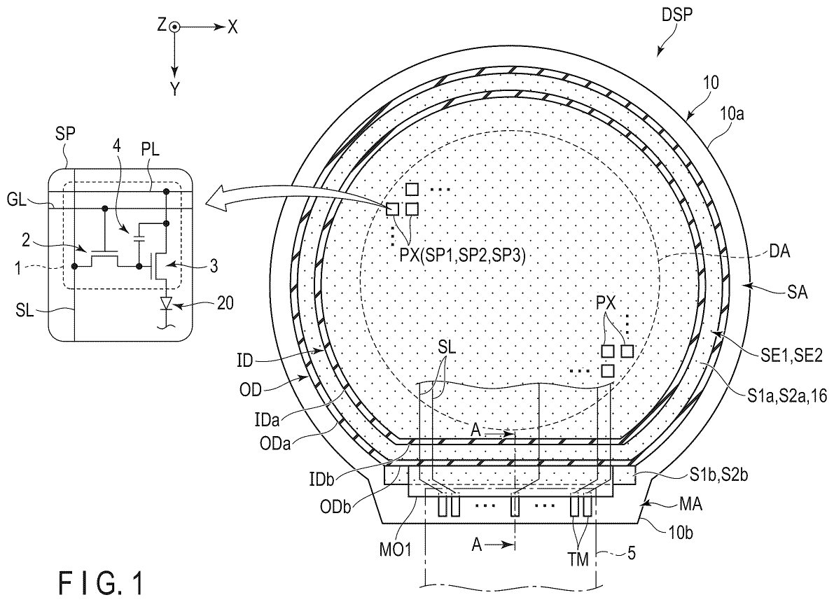

FIG. 1 is a plan view showing a schematic configuration example of a display device DSP. The display device DSP shown in FIG. 1 as an example is a display device including an organic light emitting diode (OLED) as a display element. However, the display device DSP may be a liquid crystal display device including a liquid crystal layer as a display element or a light emitting diode (LED) display device including an LED as a display element.

The display device DSP comprises a substrate 10, a plurality of conductive terminals TM, and a flexible substrate 5. The substrate 10 includes a circular body portion 10a and an extending portion 10b extending from the body portion 10a in the second direction Y. The extending portion 10b has a trapezoidal shape whose width in the first direction X decreases as being remote form the body portion 10a. The shape of the substrate 10 in a plan view is not limited to a trapezoidal shape and may be another shape such as a rectangular shape, a square shape, or an elliptic shape. The substrate 10 is formed of, for example, an insulating material such as glass or plastic.

The display device DSP further comprises a display area DA, which displays an image, and a surrounding area SA, which surrounds the display area DA. The display area DA overlaps with the body portion 10a in plan view. In the present embodiment, the display area DA is circular as seen in plan view. The shape of the display area DA in plan view may be another shape such as a rectangular shape, a square shape, or an elliptic shape.

The surrounding area SA includes a mounting area MA. The mounting area MA corresponds to an area overlapping with the extending portion 10b in plan view. The plurality of terminals TM are arranged in the mounting area MA (surrounding area SA). In the example in FIG. 1, the plurality of terminals TM are arranged at regular intervals in the first direction X. The flexible substrate 5 is connected to the plurality of terminals TM by an adhesive AD2 to be described later. In addition to the flexible substrate 5, an IC chip and the like may be further mounted on the mounting area MA.

The display area DA includes a plurality of pixels PX arrayed in a matrix in the first direction X and the second direction Y. Each of the pixels PX comprises a plurality of sub-pixels SP. For example, the pixel PX comprises a red sub-pixel SP1, a green sub-pixel SP2, and a blue sub-pixel SP3. In addition to the sub-pixels of the above three colors, the pixel PX may comprise four or more sub-pixels including a sub-pixel of another color such as white.

The sub-pixel SP comprises a pixel circuit 1 and a display element 20 driven by the pixel circuit 1. The pixel circuit 1 comprises a pixel switch 2, a drive transistor 3, and a capacitor 4. The pixel switch 2 and the drive transistor 3 are, for example, switching elements consisting of thin-film transistors.

In the pixel switch 2, a gate electrode is connected to a scanning line GL. One of the source electrode and drain electrode of the pixel switch 2 is connected to a signal line SL. The other is connected to the gate electrode of the drive transistor 3 and the capacitor 4. For example, the scanning lines GL extend in the first direction X and the signal lines SL extend in the second direction Y. The signal line SL connects the pixel circuit 1 with the terminal TM. In the drive transistor 3, one of the source electrode and the drain electrode is connected to a power line PL and the capacitor 4, and the other is connected to an anode of the display element 20. The configuration of the pixel circuit 1 is not limited to the example shown in the figure.

The display element 20 is an organic light emitting diode (OLED) in the example in FIG. 1. For example, the sub-pixel SP1 comprises a display element that emits light corresponding to a red wavelength, the sub-pixel SP2 comprises a display element that emits light corresponding to a green wavelength, and the sub-pixel SP3 comprises a display element that emits light corresponding to a blue wavelength. The display device DSP further comprises an inner dam ID surrounding the display area DA and an outer dam OD surrounding the display area DA and the inner dam ID. Each of the inner dam ID and the outer dam OD is arranged in the surrounding area SA. The inner dam ID includes an arc portion IDa and a straight portion IDb, which extends in the first direction X. The outer dam OD includes an arc portion ODa and a straight portion ODb, which extends in the first direction X. Centers of the arc portion IDa, the arc portion ODa, the display area DA, and the body portion 10a are the same. Centers of the arc portion IDa, the arc portion ODa, the display area DA, and the body portion 10a may be different from one another. The straight portion IDb and the straight portion ODb are located between the display area DA and the plurality of terminals TM. The number of the dams which the display device DSP comprises is not limited to two: one inner dam ID and one outer dam OD. The number of dams may be one or may be three or more.

The display device DSP further comprises a sealing layer SE1, a sealing layer SE2, a polarizer 16, and a moisture-proof member MO1. Dotted areas in FIG. 1 correspond to the sealing layer SE1 and the sealing layer SE2. Each of the sealing layer SE1 and the sealing layer SE2 overlaps with the inner dam ID and the outer dam OD in plan view.

The sealing layer SE1 includes a circular body portion S1a and an extending portion S1b extending from the body portion S1a in the second direction Y. The sealing layer SE2 includes a circular body portion S2a and an extending portion S2b extending from the body portion S2a in the second direction Y. The body portion S1a, the body portion S2a, and the polarizer 16 entirely overlap with an area surrounded by the outer dam OD in plan view. The body portion S1a, the body portion S2a, and the polarizer 16 may be larger than or smaller than the area surrounded by the outer dam OD in plan view. The sizes of the body portion S1a, the body portion S2a, and the polarizer 16 may be different from one another.

Each of the boundary between the body portion S1a and the extending portion S1b and the boundary between the body portion S2a and the extending portion S2b may overlap with the straight portion ODb of the outer dam OD in plan view. In the example shown in FIG. 1, the extending portion S1b and the extending portion S2b are formed in a rectangular shape having long sides overlapping with the straight portion ODb in plan view. In addition, in the example shown in FIG. 1, the extending portion S1b and the extending portion S2b do not overlap with the flexible substrate 5 in plan view.

In the example in FIG. 1, the moisture-proof member MO1 is formed in a rectangular shape having long sides overlapping with the straight portion ODb in plan view. The moisture-proof member MO1 overlaps with the extending portion S1b, the extending portion S2b, and the flexible substrate 5 in plan view.

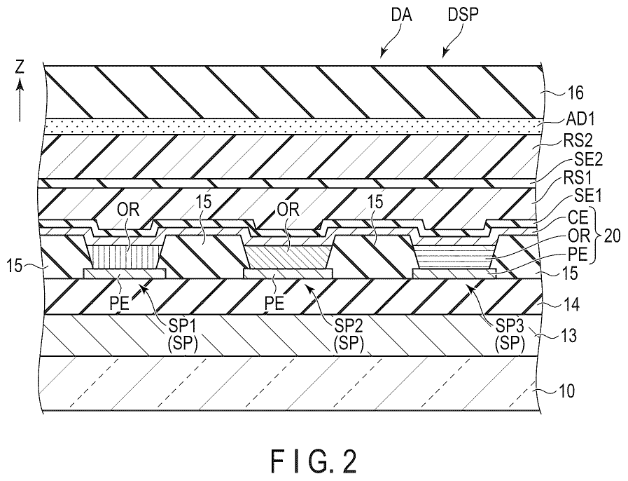

FIG. 2 is a schematic cross-sectional view of the display device DSP in the display area DA. The display device DSP further comprises a circuit layer 13, an insulating layer 14, a rib 15, a resin layer RS1, a resin layer RS2, and an adhesive AD1. The display element 20 includes a pixel electrode PE, an organic layer OR, and a common electrode CE.

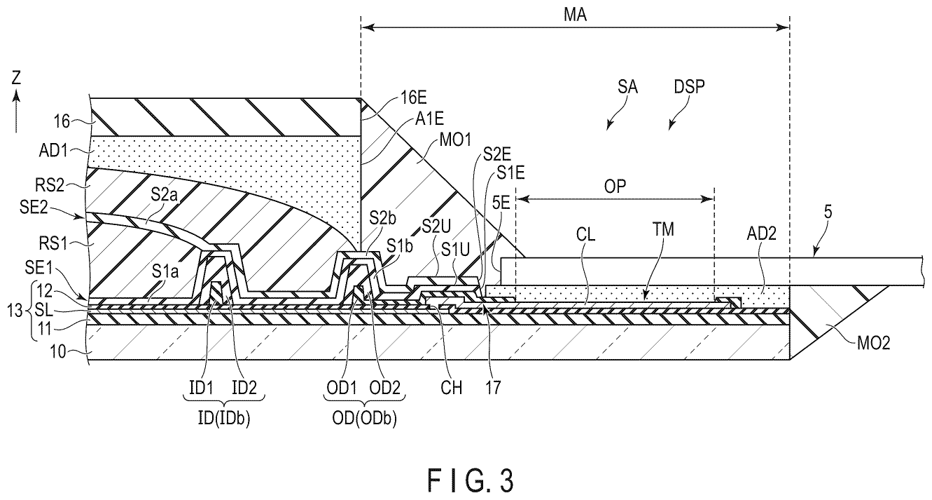

The circuit layer 13 is provided on the substrate 10 described above. The circuit layer 13 includes various circuits such as the pixel circuit 1 shown in FIG. 1 and various lines such as the scanning line GL, the signal line SL, and the power line PL. As described in detail later, the circuit layer 13 includes an insulating layer 11 and an insulating layer 12 (refer to FIG. 3). The circuit layer 13 is covered with the insulating layer 14. The insulating layer 14 has a function of flattening irregularities formed by the circuit layer 13. The insulating layer 14 is formed of an organic material. The display element 20 is arranged above the substrate 10.

Each of the plurality of pixel electrodes PE is arranged on the insulating layer 14. Though not shown in FIG. 2, the pixel electrode PE is electrically connected with the pixel electrode 1 shown in FIG. 1 through a contact hole penetrating the insulating layer 14.

The end portions of the pixel electrode PE

are covered with the rib 15. The rib 15 is formed in a grating shape surrounding the plurality of sub-pixels SP in plan view. The rib 15 is formed of, for example, an organic material.

The organic layer OR is arranged on the pixel electrode PE. The common electrode CE is arranged on the organic layer OR and the rib 15. For example, the common electrode CE is formed to spread across the sub-pixels SP.

The pixel electrode PE may be formed of a transparent conductive material such as an indium tin oxide (ITO) or an indium zinc oxide (IZO) or may be a stacked layer body of the transparent conductive material and a metal material. The common electrode CE is formed of a metal material such as magnesium and silver. Further, the common electrode CE may be formed of a transparent conductive material such as ITO or IZO. For example, the pixel electrode PE correspond to the anode of the display element 20, and the common electrode CE corresponds to a cathode of the display element 20.

The organic layer OR emits light according to an electric current flowing between the pixel electrode PE and the common electrode CE. For example, the organic layer OR comprises a multilayer structure consisting of a hole injection layer, a hole transport layer, an electron blocking layer, a light emitting layer, a hole blocking layer, an electron transport layer, and an electron injection layer. The organic layer OR may comprise a tandem structure including a plurality of light emitting layers.

The sealing layer SE1 covers the display element 20. More specifically, the sealing layer SE1 covers the common electrode CE. The resin layer RS1 is arranged on the sealing layer SE1. The sealing layer SE2 covers the resin layer RS1. The resin layer RS2 is arranged on the sealing layer SE2. The polarizer 16 is arranged above the sealing layer SE2. More specifically, the polarizer 16 is bonded to the resin layer RS2 by the adhesive AD1.

The sealing layer SE1 and the sealing layer SE2 are formed of, for example, inorganic material such as silicon nitride (SiNx), silicon oxide (Siox), and silicon oxynitride (SiON). The resin layer RS1 and the resin layer RS2 are formed of, for example, a resinous material (organic insulating material) such as acrylic resin. The adhesive AD1 is formed of, for example, optical clear adhesive (OCA) or the like.

FIG. 3 is a schematic cross-sectional view of the display device DSP along line A-A line in FIG. 1. The circuit layer 13 includes the insulating layer 11, the insulating layer 12, and the signal line SL. The insulating layer 11 covers the substrate 10. The signal line SL is arranged on the first insulating layer 11. The insulating layer 12 covers the signal line SL. Each of the insulating layer 11 and the insulating layer 12 is formed of, for example, an inorganic material such as silicon nitride or silicon oxide.

The display device DSP further comprises the inner dam ID, the outer dam OD, the moisture-proof member MO1, a conductive layer CL, an insulating layer 17, and a moisture-proof member MO2.

The inner dam ID and the outer dam OD are arranged on the insulating layer 12. The inner dam ID includes a protrusion ID1 and a protrusion ID2. The protrusion ID2 covers the protrusion ID1. The outer dam OD includes the protrusion OD1 and the protrusion OD2. The protrusion OD2 covers the protrusion OD1. The protrusion OD1 includes a part of the insulating layer 17. The inner dam ID has a function of damming up the resin layer RS1. The outer dam OD has a function of damming up the resin layer RS2.

In FIG. 3, an end portion 16E of the polarizer 16 is located directly above the outer dam OD. In other words, the outer dam OD overlaps with the end portion 16E of the polarizer 16 in plan view. The outer dam OD may not overlap with the end portion 16E in plan view.

The conductive layer CL is arranged on the insulating layer 12 in the mounting area MA. The conductive layer CL is electrically connected to the signal line SL through a contact hole CH penetrating the insulating layer 12.

The insulating layer 17 is arranged in the surrounding area SA. The insulating layer 17 covers the conductive layer CL. The protrusion ID1, the protrusion OD1, and the insulating layer 17 are formed, for example, of the same organic material as the insulating layer 14 shown in FIG. 2 and in the same manufacturing process as the insulating layer 14 shown in FIG. 2. The protrusion ID2 and the protrusion OD2 are formed, for example, of the same organic material as the rib 15 shown in FIG. 2 and in the same manufacturing process as the rib 15 shown in FIG. 2.

The insulating layer 17 overlaps with an aperture OP overlapping with the terminal TM. The flexible substrate 5 is bonded to the conductive layer CL through the aperture OP by the adhesive AD2. In the example in FIG. 3, the adhesive AD2 covers a part of the insulating layer 12 and a part of the insulating layer 17. For example, a conductive member such as an anisotropic conductive film may be used as the adhesive AD2.

Each of the sealing layer SE1 and the sealing layer SE2 covers the inner dam ID (straight portion IDb) and the outer dam OD (straight portion ODb). In the example in FIG. 3, the end portion of the resin layer RS1 is located in the vicinity of the inner dam ID. In addition, the end portion of the resin layer RS2 is located in the vicinity of the outer dam OD. The sealing layer SE1 is provided on the resin layer 17. In an area closer to the terminal TM than the end portion of the resin layer RS1 is, an upper surface S1U of the sealing layer SE1 is in contact with the sealing layer SE2.

An end portion S1E of the sealing layer SE1 and an end portion S2E of the sealing layer SE2 are closer to the terminal TM than the end portion 16E of the polarizer 16 is. More specifically, each of the end portion S1E and the end portion S2E is located between the end portion 16E and the aperture OP. In the example in FIG. 3, the end portion S1E and the end portion S2E are not in contact with the adhesive AD2. The end portion S1E and the end portion S2E are arranged on the insulating layer 17. In FIG. 3, the end portion S1E overlaps with the end portion S2E. The end portion S1E may not overlap with the end portion S2E.

The moisture-proof member MO1 is arranged above the insulating layer 17 and is in contact with the end portion 16E of the polarizer 16. The moisture-proof member MO1 overlaps with the end portion S1E of the sealing layer SE1 and the end portion S2E of the sealing layer SE2. In FIG. 3, the moisture-proof member MO1 covers the end portion S1E, the end portion S2E, and an end portion 5E of the flexible substrate 5. In the example in FIG. 3, the moisture-proof member MO1 is in contact with an upper surface S2U of the sealing layer SE2. In the mounting area MA, the sealing layer SE1 and the sealing layer SE2 are located between the insulating layer 17 and the moisture-proof member MO1. That is, each of a part of the sealing layer SE1 and a part of the sealing layer SE2 is arranged between the insulating layer 17 and the moisture-proof member MO1. In FIG. 3, a moisture-proof member MO2 is in contact with the substrate 10, the insulating layer 11, the adhesive AD2, and the flexible substrate 5.

The moisture-proof member MO1 and the moisture-proof member MO2 are formed of, for example, resin material such as an epoxy resin and an acrylic resin. The moisture-proof member MO1 has a function of preventing moisture from infiltrating the mount area MA, for example, between the end portion 16E of the polarizer 16 and the end portion 5E of the flexible substrate 5. The moisture-proof member MO2 has a function of preventing moisture from infiltrating the mounting area MA from the end portion of the substrate 10.

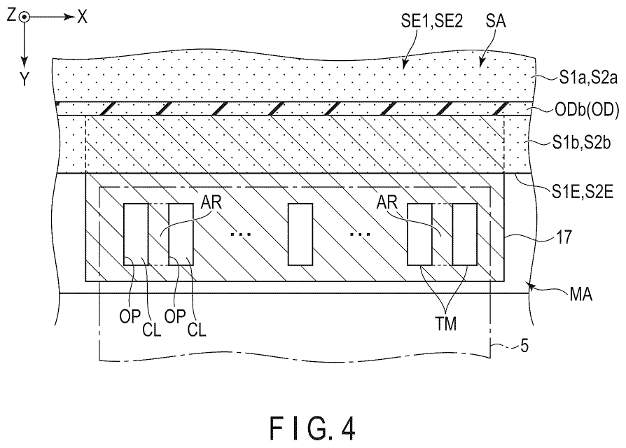

FIG. 4 is a schematic plan view showing the terminal TM in enlarged manner. Next, effects exhibited by the display device DSP according to the present embodiment will be described with reference to FIG. 3 and FIG. 4. An issue that may occur in a case where the end portion SIE of the sealing layer SE1 and the end portion S2E of the sealing layer SE2 are located closer to the display area DA shown in FIG. 1 than the end portion 16E of the polarizer 16 is will be described below. A contraction of the polarizer 16 due to a temperature change may form gaps between the end portion 16E and the moisture-proof member MO1. The outer dam OD located directly under the end portion 16E is not covered with the sealing layer SE1 and the sealing layer SE2. Thus, a moisture that has infiltrated the gaps reaches the protrusion OD2 through an end portion ALE of the adhesive AD1. The protrusion OD2 and the insulating layer 17 are formed of organic materials and thus are easily penetrated by moisture. Therefore, the moisture that has reached the protrusion OD2 penetrates into the terminal TM through the insulating layer 17. When moisture penetrates into an area AR shown in FIG. 4 (an area between adjacent terminals TM), electricity flows between the adjacent terminals TM via moisture. As a result, the terminals TM may be corrode due to a potential difference between the terminal TM (conductive layer CL) and moisture and may become easily detachable.

In the present embodiment, the end portion S1E of the sealing layer SE1 and the end portion S2E of the sealing layer SE2 are closer to the terminal TM than the end portion 16E of the polarizer 16 is. Therefore, in FIG. 3, moisture that has infiltrated from gaps between the end portion 16E and the moisture-proof member MO1 will move along the end portion ALE of the adhesive AD1 and reach the sealing layer SE2 covering the outer dam OD. The sealing layer SE1 and the sealing layer SE2 are formed of inorganic material and thus are not easily penetrated by moisture. Therefore, the infiltration of moisture to the mounting area MA can be suppressed.

In addition, the infiltration of moisture to the mounting area MA can be further suppressed by stacking the sealing layer SE1 and the sealing layer SE2, which are not easily penetrated by moisture. The sealing layers may be stacked layer of three or more layers. As described in detail below, the sealing layer may be a single-layer having the sealing layer SE1 or the sealing layer SE2.

The display device DSP comprises the moisture-proof member MO1 and the moisture-proof member MO2. The infiltration of moisture to the mounting area MA can be further suppressed. Further, the infiltration of moisture between the end portion 5E and the end portion S1E and the end portion S2E can be suppressed by the moisture-proof member MO1 covering the end portion 5E of the flexible substrate 5.

Next, another configuration example of the display device DSP will be described. In each example, the same or similar elements as those of the display device DSP described above are referred to by the same reference numbers and explanations of these elements are omitted.

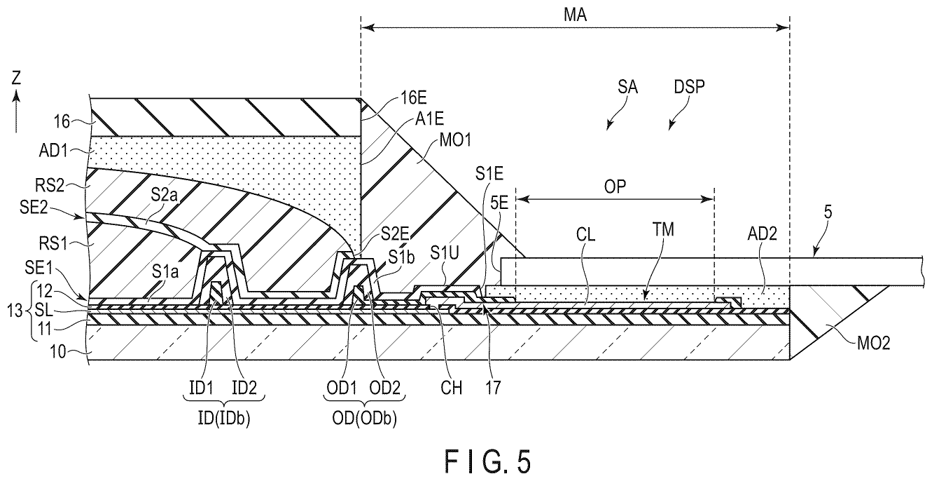

FIG. 5 is a cross-sectional view showing another configuration example of the display device DSP. In the example shown in FIG. 5, the end portion S1E of the sealing layer SE1 is closer to the terminal TM than the end portion 16E of the polarizer 16 is, and the end portion S2E of the sealing layer SE2 is closer to the inner dam ID than the end portion 16E of the polarizer 16 is. In other words, the sealing layer SE1 is located directly below the end portion 16E, but the sealing layer SE2 is not located directly below the end portion 16E. The moisture-proof member MO1 is in contact with the upper surface SIU of the sealing layer SE1 in the mounting area MA.

In the display device DSP having this configuration as well, the sealing layer SE1 can prevent moisture from infiltrating the mounting area MA. The display device DSP of FIG. 5 can achieve advantages similar to the above advantages.

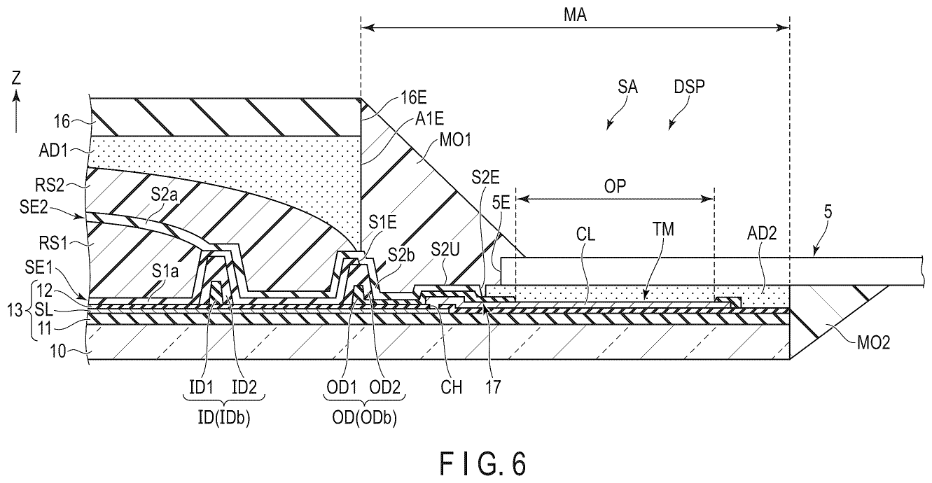

FIG. 6 is a cross-sectional view showing yet another configuration example of the display device DSP. In the example shown in FIG. 6, the end portion S2E of the sealing layer SE2 is closer to the terminal TM than the end portion 16E of the polarizer 16 is, and the end portion S1E of the sealing layer SE1 is closer to the inner dam ID than the end portion 16E of the polarizer 16 is. In other words, the sealing layer SE2 is located directly below the end portion 16E, but the sealing layer SE1 is not located directly below the end portion 16E.

In the display device DSP having this configuration as well, the sealing layer SE2 can prevent moisture from infiltrating the mounting area MA. The display device DSP of FIG. 6 can achieve advantages similar to the above advantages.

In the above example, for example, the sealing layer SE1 corresponds to a first sealing layer, the sealing layer SE2 corresponds to a second sealing layer, and the outer dam OD corresponds to a protrusion.

All of the display devices that can be implemented by a person of ordinary skill in the art through arbitrary design changes to the display device described above as the embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device, comprising:
a substrate;
a display area displaying an image;
a surrounding area surrounding the display area;
a display element arranged above the substrate;
a first sealing layer formed of an inorganic material and covering the display element;
a resin layer arranged on the first sealing layer;
a second sealing layer formed of an inorganic material and covering the resin layer;
a conductive terminal arranged in the surrounding area; and
a polarizer arranged above the second sealing layer, wherein
at least one of an end portion of the first sealing layer and an end portion of the second sealing layer is located closer to the terminal than an end portion of the polarizer is.

2. The display device of claim 1, wherein
each of the end portion of the first sealing layer and the end portion of the second sealing layer is located closer to the terminal than the end portion of the polarizer is.

3. The display device of claim 2, wherein
the end portion of the first sealing layer overlaps with the end portion of the second sealing layer.

4. The display device of claim 1, further comprising:
a protrusion surrounding the display area, wherein
the end portion of the polarizer is arranged directly above the protrusion, and
each of the first sealing layer and the second sealing layer overlaps with the protrusion in plan view.

5. The display device of claim 4, wherein the protrusion includes a part located between the display area and the terminal, and
at least one of the first sealing layer and the second sealing layer covers the part of the protrusion.

6. The display device of claim 1, further comprising:
an insulating layer formed of an organic material, having an aperture overlapping with the terminal, and arranged in the surrounding area, wherein
at least one of the first sealing layer and the second sealing layer is arranged on the insulating layer.

7. The display device of claim 6, wherein at least one of the end portion of the first sealing layer and the end portion of the second sealing layer is located between the end portion of the polarizer and the aperture.

8. The display device of claim 1, further comprising:
a moisture-proof member in contact with the end portion of the polarizer and an upper surface of at least one of the first sealing layer and the second sealing layer.

9. The display device of claim 8, wherein
the moisture-proof member overlaps with at least one of the first sealing layer and the second sealing layer.

10. The display device of claim 8, further comprising:
a flexible substrate connected with the terminal, wherein
the moisture-proof member covers an end portion of the flexible substrate.

11. The display device of claim 1, further comprising:
a protrusion located between the display area and the terminal and overlapping with the end portion of the polarizer in plan view;
an insulating layer formed of an organic material, including an aperture overlapping with the terminal, and arranged in the surrounding area; and
a moisture-proof member in contact with the end portion of the polarizer and located above the insulating layer, wherein
the protrusion includes a part of the insulating layer,
each of the first sealing layer and the second sealing layer covers the protrusion, and
each of a part of the first sealing layer and a part of the second sealing layer is located between the insulating layer and the moisture-proof member.
